(19) United States
(12) Patent Application Publication
(10) Pub. No.: US 2026/0176761 A1
(43) Pub. Date: Jun. 25, 2026

(54) METHOD AND SYSTEM FOR FORMING METAL PHOSPHIDE

(71) Applicant: ASM IP Holding B.V., Almere (NL)

(72) Inventor: Charles Dezelah, Helsinki (FI)

(21) Appl. No.: 19/424,583

(22) Filed: Dec. 18, 2025

Related U.S. Application Data
(60) Provisional application No. 63/738,229, filed on Dec. 23, 2024.

(51) Int. Cl. C23C 16/455; C23C 16/30; H10P 14/43

(52) U.S. Cl. CPC C23C 16/45553; C23C 16/30; C23C 16/45527; H10P 14/43

(57) ABSTRACT

A method of forming a metal phosphide film on a substrate using a cyclical deposition process includes contacting the substrate with a vapor-phase metal precursor, contacting the substrate with a vapor-phase halogenating agent, and contacting the substrate with a vapor-phase phosphorus-containing precursor. A method of filling a gap includes placing a substrate in a reaction chamber, wherein the substrate comprises a gap; forming a flowable metal halide on the substrate to fill the gap; and converting the flowable metal halide into a metal phosphide.

### CROSS-REFERENCE TO RELATED APPLICATIONS

This application claims priority to U.S. Provisional Patent Application Ser. No. 63/738,229 filed Dec. 23, 2024 and titled METHOD AND SYSTEM FOR FORMING METAL PHOSPHIDE, the disclosure of which is hereby incorporated by reference in its entirety.

### BACKGROUND OF THE INVENTION

### Field of the Invention

The present disclosure relates to semiconductor technology, and, in particular, it relates to a method and a system for forming a metal phosphide.

### Background

The scaling of semiconductor devices (such as logic devices and memory devices, for example) has led to significant improvements in the speed and density of integrated circuits. However, conventional techniques for scaling-down the size of devices face significant challenges for future technology nodes. One challenge has been to find suitable ways of depositing thin film materials capable of filling substrate features without leaving a gap, a void, or a seam in the feature. This is inherently difficult to do, especially using an ALD-like cyclic approach which tends to more readily produce conformal layers.

Any discussion, including discussion of problems and solutions, set forth in this section has been included in this disclosure solely for the purpose of providing a context for the present disclosure. This discussion should not be taken as an admission that any or all of the information was known at the time the invention was made or otherwise constitutes prior art.

### BRIEF SUMMARY OF THE INVENTION

This summary may introduce a selection of concepts in a simplified form, which may be described in further detail below. This summary is not intended to necessarily identify key features or essential features of the claimed subject matter, nor is it intended to be used to limit the scope of the claimed subject matter.

One aspect of the present disclosure provides a method of forming a metal phosphide film on a substrate using a cyclical deposition process. The method includes contacting the substrate with a vapor-phase metal precursor. The method includes contacting the substrate with a vapor-phase halogenating agent. The method includes contacting the substrate with a vapor-phase phosphorus-containing precursor.

Another aspect of the present disclosure provides a method of filling a gap. The method includes placing a substrate in a reaction chamber, wherein the substrate comprises a gap. The method includes forming a flowable metal halide on the substrate to fill the gap. The method includes converting the flowable metal halide into a metal phosphide.

Yet a further aspect of the present disclosure provides a system for forming a metal phosphide film. The system includes a reaction chamber, a first precursor source comprising a metal precursor, a second precursor source comprising a halogenating agent, a third precursor source comprising a phosphorus-containing precursor, and a controller. The controller is configured to control gas flow into the reaction chamber to form a metal phosphide on a substrate by means of a method as described herein.

For the purposes of the current disclosure, the term “step” should be understood broadly, and not limited to a discrete stage preceding or following another step. In some embodiments, process steps may be discrete. In some embodiments, two parts of a process, indicated as steps can be performed alternately and sequentially. In some embodiments, two steps of a process may overlap at least partly.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWINGS

The present invention can be more fully understood by reading the subsequent detailed description and examples with references made to the accompanying drawings, wherein:

FIG. 1 is a flowchart of a method of forming a metal phosphide film on a substrate using a cyclical deposition process according to an embodiment of the present disclosure;

FIG. 2 is a flowchart of a method of filling a gap according to an embodiment of the present disclosure; and

FIG. 3 is a schematic view of a system according to an embodiment of the present disclosure.

### DETAILED DESCRIPTION OF THE INVENTION

The following description is made for the purpose of illustrating the general principles of the disclosure and should not be taken in a limiting sense. The scope of the disclosure is determined by reference to the appended claims. Reference will now be made in detail to exemplary embodiments of the present disclosure, examples of which are illustrated in the accompanying drawings. Whenever possible, the same reference numbers are used in the drawings and descriptions to refer to the same or similar parts.

In the disclosure, the terms “about”, “equal to”, “equal” or “the same”, “substantially” or “approximately” usually indicates a value of a given value or range that varies within 20%, or a value of a given value or range that varies within 10%, within 5%, or within 3%, or within 2%, or within 1%, or within 0.5%. Further, any two numbers of a variable can constitute a workable range of the variable, and any ranges indicated may include or exclude the endpoints. Additionally, any values of variables indicated may refer to precise values or approximate values and include equivalents, and may refer to average, median, representative, majority, or the like.

As used herein, the term “precursor” can refer to a compound that participates in the chemical reaction that produces another compound. In this disclosure, the term “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. A seal gas may be an inert gas. For example, a seal gas may be nitrogen or a noble gas, such as argon or helium.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, gaps, voids, seams and the like formed within or on at least a portion of the substrate. By way of examples, a substrate can include at least one of bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may include material or a layer with pinholes and/or isolated islands. A film or layer may be at least partially continuous. A film or layer may be patterned, e.g. subdivided, and may be included in a plurality of semiconductor devices.

In this disclosure, the term “deposition process” as used herein can refer to the introduction of precursors into a reaction chamber to deposit a layer over a substrate. The term “cyclical deposition process” can refer to a sequential introduction of precursors into a reaction chamber to deposit a layer or a film over a substrate and includes processing techniques such as atomic layer deposition (ALD), cyclical chemical vapor deposition (cyclical CVD), and hybrid cyclical deposition processes that include an ALD and a CVD.

In this disclosure, the term silylphosphine refers to molecules comprising a trivalent phosphorus atom and at least one silicon atom. A silylphosphine according to the current disclosure may be an alkylsilylphosphine. In some embodiments, a silylphosphine comprises one phosphorus atom and at least one silicon atom. In some embodiments, a silylphosphine comprises one phosphorus atom and one silicon atom. In some embodiments, a silylphosphine comprises one phosphorus atom and two silicon atoms. Each of the one or more silicon atoms may comprise one or more alkyl substituents. In some embodiments, the alkylsilylphosphine is selected from tris-trimethylsilylphosphine and tris-triethylsilylphosphine. In some embodiments, the alkylsilylphosphine is trimethylsilylphosphine. In some embodiments, the alkylsilylphosphine is tris-triethylsilylphosphine.

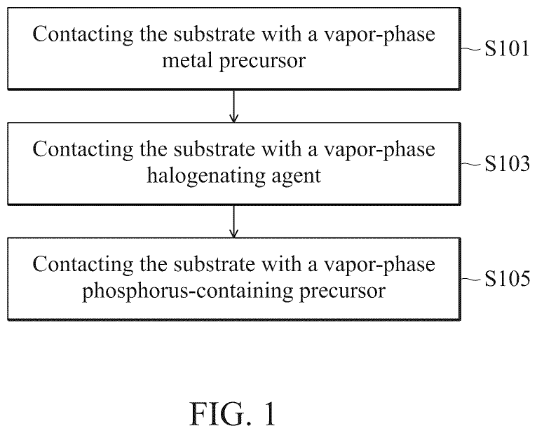

One aspect of the present disclosure is providing a method of forming a metal phosphide film on a substrate using a cyclical deposition process. FIG. 1 is a flowchart of a method of forming a metal phosphide film on a substrate using a cyclical deposition process according to an embodiment of the present disclosure. As shown in FIG. 1 the method includes a step S101 of contacting the substrate with a vapor-phase metal precursor; a step S103 of contacting the substrate with a vapor-phase halogenating agent; and a step S105 of contacting the substrate with a vapor-phase phosphorus-containing precursor.

In some embodiments, step S101, step S103, and step S105 may be performed in the sequence shown in FIG. 1. That is, the method includes sequential exposure of the substrate to a vapor-phase metal precursor, followed by a vapor-phase halogenating agent, and then a vapor-phase phosphorus-containing precursor. However, the step S101, step S103, and step S105 may be performed in any suitable order. For example, in some embodiments, step S103 of contacting the substrate with the vapor-phase halogenating agent may be performed before step S101 of contacting the substrate with the vapor-phase metal precursor, and in some embodiments, step S105 of contacting the substrate with the vapor-phase phosphorus-containing precursor may be performed before step S103 of contacting the substrate with the vapor-phase halogenating agent.

A deposition cycle including step S101, step S103, and step S105 may be performed one or more times until a sufficient amount of metal phosphide is deposited or the gap is filled to a desired degree. Furthermore, in each deposition cycle, each of step S101, step S103, and step S105 may be performed one or more times. In some embodiments, at least one of step S101, step S103, and step S105 may be performed more than one time in one deposition cycle. In some embodiments, step S101 of contacting the substrate with the vapor-phase metal precursor and step S103 of contacting the substrate with the vapor-phase halogenating agent may be repeated more than one time (e.g., 2 or 3 or 4 times) before step S105 of contacting the substrate with the vapor-phase phosphorus-containing precursor in one deposition cycle. In other embodiments, step S105 of contacting the substrate with the vapor-phase phosphorus-containing precursor may be performed more than one time (e.g., 2 or 3 or 4 times) in one deposition cycle.

The method of the present disclosure is performed on a substrate. In some embodiments, each step of the method may be performed on the same surface of the substrate. That is, for example, step S101 of contacting the substrate with the vapor-phase metal precursor and step S103 of contacting the substrate with the vapor-phase halogenating agent may be performed on the same surface of the substrate, but the disclosure is not limited thereto. The substrate may include any suitable materials. In some embodiments, the substrate may include a monocrystalline silicon wafer, monocrystalline germanium wafer, gallium arsenide wafer, quartz, sapphire, glass, steel, aluminum, silicon-on-insulator substrate, plastics, and the like, but the disclosure is not limited thereto.

In some embodiments, the substrate may include gaps, voids, seams, or a combination thereof, and the method of the present disclosure may be useful for filling such gaps, voids, or seams. The gap, the void, or the seam in the substrate may have a depth of at least 5 nm to at most 500 nm, a width of at least 10 nm to at most 10,000 nm, and/or a length of at least 10 nm to at most 10,000 nm. In the current disclosure, a width and a length are distances of the gap, void or seam along the surface of the substrate. In some embodiments, the width and the length of the gap, void or seam are the same. In some embodiments, the width and the length of the gap, void or seam are different. In such embodiments, the length is the larger of the two. In some embodiments, the gap, the void, or the seam in the substrate may have a depth of at least 10 nm to at most 250 nm, or from at least 20 nm to at most 200 nm, or from at least 50 nm to at most 150 nm, or from at least 100 nm to at most 150 nm. In some embodiments, the gap, the void, or the seam in the substrate may have a width of at least 20 nm to at most 5,000 nm, or from at least 40 nm to at most 2,500 nm, or from at least 80 nm to at most 1,000 nm, or from at least 100 nm to at most 500 nm, or from at least 150 nm to at most 400 nm, or from at least 200 nm to at most 300 nm. In some embodiments, the gap, the void, or the seam in the substrate may have a length of at least 20 nm to at most 5,000 nm, or from at least 40 nm to at most 2,500 nm, or from at least 80 nm to at most 1,000 nm, or from at least 100 nm to at most 500 nm, or from at least 150 nm to at most 400 nm, or from at least 200 nm to at most 300 nm.

In some embodiments, the presently described methods are carried out at a substrate temperature of less than 800° C., or of at least 50° C. to at most 500° C., or of at least 100° C. to at most 300° C., or of at least −25° C. to at most 400° C., or of at least 0° C. to at most 200° C., or of at least 25° C. to at most 150° C., or of at least 50° C. to at most 100° C.

In some embodiments, the presently described methods are carried out at a pressure of less than 760 Torr or of at least 0.2 Torr to at most 760 Torr, of at least 1 Torr to at most 100 Torr, or of at least 1 Torr to at most 30 Torr, or of at least 1 Torr to at most 200 Torr, or of at least 1 Torr to at most 10 Torr.

In some embodiments, the method of the present disclosure may include an atomic layer deposition (ALD) process, cyclical chemical vapor deposition (cyclical CVD) process, and hybrid cyclical deposition processes that include an ALD and a CVD. The following uses a method of the present disclosure including an ALD process and step S101, step S103, and step S105 are performed in sequence as an example for further description. However, the method of the present disclosure is not limited to the following example.

In some embodiments, step S101 may be performed at a substrate temperature of less than 800° C., or of at least 50° C. to at most 500° C., or of at least 100° C. to at most 300° C. In some embodiments, step S101 may be performed at a substrate temperature of at least −25° C. to at most 300° C., or of at least 0° C. to at most 250° C., or of at least 25° C. to at most 200° C., or of at least 50° C. to at most 150° C., or of at least 75° C. to at most 125° C.

In some embodiments, step S101 may be performed at a pressure of at most 30 Torr, at most 20 Torr, at most 10.0 Torr, or of at least 5.0 Torr, or of at least 3.0 Torr, or of at least 2.0 Torr, or of at least 1.0 Torr, or of at least 0.5 Torr, or at least 0.5 Torr to at most 30 Torr.

In some embodiments, in step S101, the vapor-phase metal precursor may be introduced in one or more pulses of from at least 0.1 s (second) to at most 1000 s, or from at least 0.1 s to at most 500 s, or from at least 0.2 s to at most 200 s, or from at least 0.2 s to at most 100 s, or from at least 0.25 s to at most 50 s, or from at least 0.25 s to at most 30 s, or from at least 0.1 s to at most 3 s, or from at least 0.1 s to at most 1 s. For example, the vapor-phase metal precursor may be introduced into the reaction chamber in one or more pulses of about 0.1 s, 0.2 s, 0.25s, 0.5 s, 1 s, 1.5 s, 2 s or 3 s.

The vapor-phase metal precursor used in step S101 may chemisorb onto the substrate, leaving metal-ligand bonds on a surface of the substrate. In this disclosure, the term “metal precursor” refers to a vaporizable compound including a metal. In some embodiments, the metal precursor may comprise a vaporizable compound including a metal and at least one ligand, wherein the at least one ligand may be a cyclopentadienyl ligand, an alkoxide ligand, an alkylamido ligand, an amidinate ligand, an alkyl ligand, a beta-diketonate ligand, an enaminolate ligand, a guanidinate ligand or a diazadiene ligand. In some embodiments, the metal precursor is a heteroleptic precursor comprising more than one ligand type. For example, a metal precursor may comprise a cyclopentadienyl ligand and an alkyl ligand. The metal may be a zero-valent atom or an ion of any metal. In some embodiments, the metal in the metal precursor is a metal capable of forming a flowable halide compound.

The metal in the metal precursor may be any metal. In some embodiments, the metal in the metal precursor may be a metal having a flowable halide. In some embodiments, the metal in the metal precursor is a group 3 to group 15 metal, a group 9 to group 10 metal, a group 13 metal, or a group 14 element (e.g. silicon).

In some embodiments, the metal in the metal precursor is a transition metal. In some embodiments, the metal in the metal precursor is a group 3 to group 6 transition metal, a group 7 to group 12 transition metal, or a group 9 to group 12 transition metal. In some embodiments, the metal in the-metal precursor is selected from group 4, group 5 and group 6 metals. In some embodiments, the metal in the metal precursor is selected from a group consisting of titanium, zirconium, hafnium, vanadium, niobium, tantalum, chromium, molybdenum and tungsten.

In some embodiments, the metal in the metal precursor is titanium. In some embodiments, the metal in the metal precursor is zirconium. In some embodiments, the metal in the metal precursor is hafnium. In some embodiments, the metal in the metal precursor is vanadium. In some embodiments, the metal in the metal precursor is niobium. In some embodiments, the metal in the metal precursor is tantalum. In some embodiments, the metal in the metal precursor is chromium. In some embodiments, the metal in the metal precursor is molybdenum. In some embodiments, the metal in the metal precursor is tungsten.

In some embodiments, the metal in the metal precursor is a rare earth metal. In some embodiments, the metal in the metal precursor is selected from a group consisting of scandium, yttrium and lanthanides. In some embodiments, the metal in the metal precursor is scandium. In some embodiments, the metal in the metal precursor is yttrium. In some embodiments, the metal in the metal precursor is selected from a group consisting of scandium and yttrium. In some embodiments, the metal in the metal precursor is a lanthanide, In some embodiments, the lanthanide is selected from a group consisting of lanthanum, cerium, praseodymium, neodymium, promethium, samarium, europium, gadolinium, terbium, dysprosium, holmium, erbium, thulium, ytterbium and lutetium.

In some embodiments, the metal in the metal precursor is a group 7 metal. In some embodiments, the metal in the metal precursor is manganese. In some embodiments, the metal in the metal precursor is rhenium. In some embodiments, the metal in the metal precursor is bohrium.

In some embodiments, the metal in the metal precursor is a group 8 metal. In some embodiments, the metal in the metal precursor is iron. In some embodiments, the metal in the − metal precursor is ruthenium. In some embodiments, the metal in the metal precursor is osmium. In some embodiments, the metal in the metal precursor is a group 9 metal. In some embodiments, the metal in the metal precursor is cobalt. In some embodiments, the metal in the metal precursor is rhodium. In some embodiments, the metal in the − metal precursor is iridium.

In some embodiments, the metal in the metal precursor is a group 10 metal. In some embodiments, the metal in the metal precursor is nickel. In some embodiments, the metal in the metal precursor is palladium. In some embodiments, the metal in the metal precursor is platinum.

In some embodiments, the metal in the metal precursor is a group 11 metal. In some embodiments, the metal in the metal precursor is copper. In some embodiments, the metal in the metal precursor is silver. In some embodiments, the metal in the metal precursor is gold.

In some embodiments, the metal in the metal precursor is a group 12 metal. In some embodiments, the metal in the metal precursor is zinc.

In some embodiments, the metal in the metal precursor is a group 13 metal. In some embodiments, the metal in the metal precursor is aluminum. In some embodiments, the metal in the metal precursor is gallium. In some embodiments, the metal in the metal precursor is indium.

In some embodiments, the metal in the metal precursor is not titanium. In some embodiments, the metal in the metal precursor is not zirconium. In some embodiments, the metal in the metal precursor is not hafnium. In some embodiments, the metal in the metal precursor is not vanadium. In some embodiments, the metal in the metal precursor is not niobium. In some embodiments, the metal in the metal precursor is not tantalum. In some embodiments, the metal in the metal precursor is not chromium. In some embodiments, the metal in the metal precursor is not molybdenum. In some embodiments, the metal in the metal precursor is not tungsten. In some embodiments, the metal in the metal precursor is not manganese. In some embodiments, the metal in the metal precursor is not rhenium. In some embodiments, the metal in the metal precursor is not iron. In some embodiments, the metal in the metal precursor is not ruthenium. In some embodiments, the metal in the metal precursor is not cobalt. In some embodiments, the metal in the metal precursor is not iridium. In some embodiments, the metal in the metal precursor is not nickel. In some embodiments, the metal in the metal precursor is not palladium. In some embodiments, the metal in the metal precursor is not platinum. In some embodiments, the metal in the metal precursor is not copper. In some embodiments, the metal in the metal precursor is not silver. In some embodiments, the metal in the metal precursor is not gold. In some embodiments, the metal in the metal precursor is not zinc. In some embodiments, the metal in the-metal precursor is not boron. In some embodiments, the metal in the metal precursor is not aluminum. In some embodiments, the metal in the metal precursor is not gallium. In some embodiments, the metal in the metal precursor is not indium. In some embodiments, the metal in the metal precursor is not tellurium.

In some embodiments, the metal in the metal precursor is selected from a group consisting of Al, In, Sn, Bi, Ge, Sb, Te, Rh, Fe, Cr, Mo, Au, Pt, Ag, Ni, Cu, Co, Zn, Nb, Ta, V, Ti, Zr, Hf, W, or a combination thereof.

In some embodiments, contacting the substrate with a vapor-phase halogenating agent in step S103 forms flowable metal halides. Without limiting the current disclosure to any specific theory, the metal-ligand bonds on the surface of the substrate may be converted into a flowable metal halide. In some embodiments, the flowable metal halide formed in step S103 may include flowable halo-oligomers/polymers that undergo chain growth as the metal precursor and the halogenating agent polymerize. In some embodiments, the flowable metal halide formed in step S103 may be a metal halide that is liquid, or that can form a liquid, under the conditions in which it is formed. Therefore, the flowable metal halide formed in step S103 may flow into gaps, voids, or seams of the substrate due to its flowability. In some embodiments, the flowable metal halide is only temporarily in a flowable state and forms a solid material in the subsequent process. For example, in some embodiments, the “flowable metal halide” may be temporarily formed through formation of liquid oligomers from gaseous monomers during a polymerization reaction, and forms a solid material as it undergoes a chemical reaction.

In some embodiments, step S103 may be performed at a substrate temperature of less than 800° C., or of at least 50° C. to at most 500° C., or of at least 100° C. to at most 350° C. In some embodiments, step S103 may be performed at a substrate temperature of at least −25° C. to at most 400° C., or of at least 0° C. to at most 250° C., or of at least 25° C. to at most 200° C., or of at least 50° C. to at most 150° C., or of at least 75° C. to at most 125° C. The step S103 may be performed at the same or a different substrate temperature than that at which step S101 is performed.

In some embodiments, step S103 may be performed at a pressure of at most 50 Torr, or at most 40.0 Torr, or at most 30.0 Torr, or at most 20.0 Torr, or at most 10.0 Torr, or at most 5.0 Torr, or of at least 5.0 Torr, or of at least 3.0 Torr, or of at least 2.0 Torr, or of at least 1.0 Torr, or of at least 0.5 Torr, or at least 0.5 to at most 50 Torr. The step S103 may be performed at the same pressure as step S101 or at different pressure.

In some embodiments, in step S103, the vapor-phase halogenating agent may be introduced in a pulse form for from at least 0.1 s (second) to at most 100 s, or from at least 0.1 s to at most 50 s, or from at least 0.1 s to at most 30 s, or from at least 0.5 s to at most 100 s, or from at least 0.5 s to at most 50 s, or from at least 0.5 s to at most 30 s, or from at least 0.1 s to at most 3 s. The vapor-phase halogenating agent may be introduced in the same or a different form as the vapor-phase metal precursor.

In some embodiments, the halogenating agent may be a diatomic halogen molecule, a hydrogen halide, an alkyl halide, an aryl halide, an acyl halide, a halosilane, a metal halide, a boron halide, phosphorus halide, sulfur halide, N-chlorosuccinimide, N-bromosuccinimide, N-iodosuccinimide, 1,1-difluoroalkylamine, or a combination thereof.

Examples of the diatomic halogen molecule include but are not limited to F₂, Cl₂, Br₂, I₂, or a combination thereof. Examples of the hydrogen halide include but are not limited to HF, HCl, HBr, HI, or a combination thereof.

An alkyl halide according to the current disclosure comprises at least one halogen atom bonded to an alkyl. In some embodiments, an alkyl halide comprises at least one halogen atom. In some embodiments, an alkyl halide contains one halogen atom. In some embodiments, an alkyl halide comprises at least two halogen atoms. In some embodiments, an alkyl halide contains two halogen atoms. In some embodiments, an alkyl halide comprises at least three halogen atoms. In some embodiments, an alkyl halide contains three halogen atoms. In some embodiments, an alkyl halide comprises at least four halogen atoms. In some embodiments, an alkyl halide contains four halogen atoms. Examples of the alkyl halide include, but are not limited to, 1-chlorohexane, 1-bromohexane, 1-iodobutane, diiodomethane (CH₂I₂), 1,2-diiodoethane(I(CH₂)₂I), or a combination thereof.

An aryl halide according to the current disclosure comprises at least one halogen atom bonded to an aryl. In some embodiments, an aryl halide comprises at least one halogen atom. In some embodiments, an aryl halide contains one halogen atom. In some embodiments, an aryl halide comprises at least two halogen atoms. In some embodiments, an aryl halide contains two halogen atoms. In some embodiments, an aryl halide comprises at least three halogen atoms. In some embodiments, an aryl halide contains three halogen atoms. In some embodiments, an aryl halide comprises at least four halogen atoms. In some embodiments, an aryl halide contains four halogen atoms. Examples of the aryl halide include, but are not limited to, chlorobenzene, bromobenzene, iodobenzene, or a combination thereof.

A halosilane according to the current disclosure comprises at least one halogen atom bonded to a silane. In some embodiments, a halosilane comprises at least one halogen atom. In some embodiments, a halosilane contains one halogen atom. In some embodiments, a halosilane comprises at least two halogen atoms. In some embodiments, a halosilane contains two halogen atoms. In some embodiments, a halosilane comprises at least three halogen atoms. In some embodiments, a halosilane contains three halogen atoms. In some embodiments, a halosilane comprises at least four halogen atoms. In some embodiments, a halosilane contains four halogen atoms. Examples of the halosilane include but are not limited to SiCl₄, SiH₂Cl₂, SiBr₄, SiH₂Br₂, SiH₂I₂, SiI₄, or a combination thereof.

Examples of the metal halides include but are not limited to TiF₄, TiCl₄, VCl₄, HfCl₄, NbCl₅, TaCl₅, TaBr₅, MoCl₅, WF₆, WCl₅, AlCl₃, AlBr₃, or a combination thereof. Examples of the volatile boron halide include but are not limited to BCl₃, BBr₃, BI₃, or a combination thereof.

Examples of the sulfur halide include but are not limited to sulfur dihalides (SX₂), disulfurs dihalides (S₂X₂), sulfur hexahalides (SX₆), sulfur tetrahalides (SX₄), thionyl halide (SOX₂), and sulfuryl halide (SO₂X₂). Examples of the phosphorus halide include but are not limited to sulfur dichloride (SCl₂), disulfur dichloride (S₂Cl₂), sulfur hexafluoride (SF₆), sulfur tetrafluoride (SF₄), sulfur dibromide (SBr₂), disulfur dibromide (S₂Br₂), sulfur diiodide (SI₂), disulfur diiodide (S₂I₂), SOCl₂, SO₂Cl₂, or SOXR¹, where X is a halogen atom and R¹ is independently C₁-C₆ alkyl group.

Examples of the phosphorus halide include but are not limited to phosphorus pentahalides (PX₅), phosphorus trihalides (PX₃), diphosphorus tetrahalides (P₂X₄), and phosphorus oxyhalides (POX₃). Examples of the phosphorus halide include but are not limited to phosphorus pentafluoride (PF₅), phosphorus pentachloride (PCl₅), phosphorus pentabromide (PBr₅), phosphorus trifluoride (PF₃), phosphorus trichloride (PCl₃), phosphorus tribromide (PBr₃), phosphorus triiodide (PI₃), diphosphorus tetrafluoride (P₂F₄), diphosphorus tetrachloride (P₂Cl₄), diphosphorus tetrabromide (P₂Br₄), POCl₃, or POXₐR²_{b}, where a is 1 or 2, b=3−a, X is a halogen atom, and R² is independently C₁-C₆ alkyl group.

1,1-difluoroalkylamine may be represented by the formula:

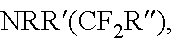

where R═C₁-C₈ alkyl or fluoroalkyl, R′═C₁-C₈ alkyl or fluoroalkyl, R″═C₁-C₈ alkyl or fluoroalkyl or chloroalkyl or chlorofluoroalkyl or alkylamino group. Any two of R, R′, or R″ can connect to each other to form a ring that is inclusive of the N atom and the CF₂ group of the above formula. Examples of the 1,1-difluoroalkylamine include but are not limited to N,N-Diethyl-1,1,2,3,3,3-hexafluoro-1-propanamine, 1,1,2,2-Tetrafluoro-N,N-dimethylethanamine, 2,2-Difluoro-1,3-dimethylimidazolidine or a combination thereof.

Examples of the acyl halide include but are not limited to oxalyl fluoride, oxalyl chloride, oxalyl bromide, acetyl chloride, acetyl fluoride, acetyl chloride, acetyl bromide, acetyl iodide, or R³COCl, where R³ is a C₁-C₁₀ alkyl or a C₆-C₁₀ aryl group. In some embodiments, the acyl halide may contain multiple acyl halide groups.

The term “C₁-C₁₀ alkyl group” used herein refers to a linear, branched, or cyclic aliphatic hydrocarbon monovalent group having 1 to 10 carbon atoms in the main carbon chain. Examples of the C₁-C₁₀ alkyl group include, but are not limited to, a methyl group, an ethyl group, a propyl group, an iso-butyl group, a sec-butyl group, a tert-butyl group, a pentyl group, an iso-amyl group, a hexyl group, a cyclohexyl group, or a cyclooctyl group. The term “C₁-C₆ alkyl group” used herein refers to a linear, branched, or cyclic aliphatic hydrocarbon monovalent group having 1 to 6 carbon atoms in the main carbon chain. Examples of the C₁-C₆ alkyl group include but are not limited to a methyl group, an ethyl group, a propyl group, an iso-butyl group, a sec-butyl group, a tert-butyl group, a pentyl group, an iso-amyl group, a hexyl group, or a cyclohexyl group.

The term “C₆-C₁₀ aryl group” used herein refers to a monovalent group having a carbocyclic aromatic system containing 6 to 10 carbon atoms. Non-limiting examples of the C₆-C₁₀ aryl group include but are not limited to a phenyl group and a naphthyl group.

In some embodiments, the flowable metal halide formed in step S103 may include CrF₅, BiF₅, GeF₂, GeF₄, SbF₃, SbF₅, AuF₃, AgF₃, TaF₅, VF₄, VF₅, TiF₄, Mo₆Cl₁₂, MoCl₄, AlCl₃, SnCl₂, ZnCl₂, NbCl₄, TaCl₅, ZrCl₄, HfCl₄, RhBr₃, FeBr₂, FeBr₃, MoBr₃, SnBr₃, InBr₃, Te₂Br, PtBr₄, NiBr₂, CuBr₂, VBr₃, AuBr, TaBr₅, ZrBr₄, VBr₃, MoI₃, AlI₃, CoI, ZnI₂, NbI₅, TaI₅, ZrI₄, HfI₄, WOBr₄, WOCl₄, NbOCl₃, V₂O₂F₄, VOCl₂, VOCl₃, VOF₃, ZrF₆(H₂O)₂, CoCl₂(H₂O)₂, or a combination thereof.

In step S105, the flowable metal halide formed in step S103 may be converted into a metal phosphide film as it undergoes a chemical reaction with the phosphorus-containing precursor. In some embodiments, step S105 may be performed at a substrate temperature of less than 800° C., or of at least −25° C. to at most 800° C., or of at least 0° C. to at most 700° C., or of at least 25° C. to at most 600° C., or of at least 50° C. to at most 400° C., or of at least 75° C. to at most 200° C., or of at least 100° C. to at most 150° C. The step S105 may be performed at the same substrate temperature as step S103 or step S101, or at a different temperature.

In some embodiments, step S105 may be performed at a pressure of at mot 10.0 Torr, or of at most 5.0 Torr, or of at most 3.0 Torr, or of at most 2.0 Torr, or of at most 1.0 Torr, or of at most 0.1 Torr, or of at most 10⁻² Torr, or of at most 10⁻³ Torr, or of at most 10⁻⁴ Torr, or of at most 10⁻⁵ Torr, or of at least 0.1 Torr to at most 10 Torr, or of at least 0.2 Torr to at most 5 Torr, or of at least 0.5 Torr to at most 2.0 Torr. The step S105 may be performed at the same or a different pressure than that at which step S103 or step S101 is performed.

In some embodiments, in step S105, the vapor-phase phosphorus-containing precursor may be introduced in a pulse form for from at least 0.1 s (second) to at most 1000 s, or from at least 0.2 s to at most 500 s, or from at least 0.5 s to at most 200 s, or from at least 1.0 s to at most 100 s, or from at least 2 s to at most 50 s, or from at least 5 s to at most 20 s. The vapor-phase phosphorus-containing precursor may be introduced in the same or a different form as the vapor-phase metal precursor or the vapor-phase halogenating agent.

The phosphorus-containing precursor may include a silylphosphine, such as an alkylsilylphosphine. In some embodiments, the silylphosphine, such as an alkylsilylphosphine may be represented by the formula:

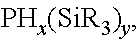

wherein x is an integer from 0 to 2, y=3−x, and R is independently hydrogen or a C₁-C₁₀ alkyl group. The definition of the term “C₁-C₁₀ alkyl group” is the same as above and is therefore not repeated.

The method is also applicable for forming a metal phosphide film containing two or more different metals. For example, a supercycle alternating between sub-cycles for two metals is outlined as follows:

$$[ ( A 1 + B + C ) x + ( A 2 + B + C ) y ] z$$

wherein A1 represents a step of contacting the substrate with a first vapor-phase metal precursor including a first metal, and A2 represents a step of contacting the substrate with a second vapor-phase metal precursor including a second metal different from the first metal. A1 and A2 similar to step S101 above. B represents a step of contacting the substrate with a vapor-phase halogenating agent, which is similar to step S103. C represents a step of contacting the substrate with a vapor-phase phosphorus-containing precursor, which is similar to step S105. In this supercycle, x refers to the number of sub-cycles for the deposition of metal phosphide containing the first metal; y refers to the number of sub-cycles for the deposition of metal phosphide containing the second metal; and z refers to the total number of supercycles to achieve the desired composition or film thickness. For clarity, as the sub-cycles are alternated in a supercycle, the order in which they are performed may be selected freely.

In some embodiments, phases B and C may be omitted from the second supercycle. In such embodiments, the process could be described as [(A1+B+C)x+A2]z.

In some embodiments, the halogenation phase can be repeated multiple times before contacting the substrate with contacting the substrate with a phosphorus-containing precursor. Such embodiments could be described as [(A1+B)a+C]z or, for two metals, as [(A1+B)a+C)x+((A2+B)b+C)y]z, wherein x, y and z are as above, and a and b denote the repetition of the halogenation phase.

In some embodiments, the method of the present disclosure may further include purging steps between each step to remove any excess precursor and/or reaction by-products. In particular, the method of the present disclosure may further include a first purging step between step S101 and step S103, and/or a second purging step between step S103 and step S105. In some embodiments, each purging step may include introducing an inert or substantially inert gas into the reaction chamber between any two steps.

The method of the present disclosure provides a method of forming a metal phosphide film using a cyclical deposition process, such as such as atomic layer deposition (ALD), cyclical chemical vapor deposition (cyclical CVD), and hybrid cyclical deposition processes that include an ALD and a CVD. In some embodiments, the metal phosphide film formed by the method of the present disclosure may fill the gaps, the voids, or the seams of the substrate by at least one of capillary forces, surface tension, and gravity. The gap can be suitably filled with the metal phosphide film to form a substrate without gaps (e.g. no gap having a size of approximately 5 nm or greater), voids (e.g., no void having a size of approximately 5 nm or greater in diameter), or seams (e.g. no seam having a length of approximately 5 nm or greater). The method of the present disclosure can be advantageously used in the field of integrated circuit manufacture.

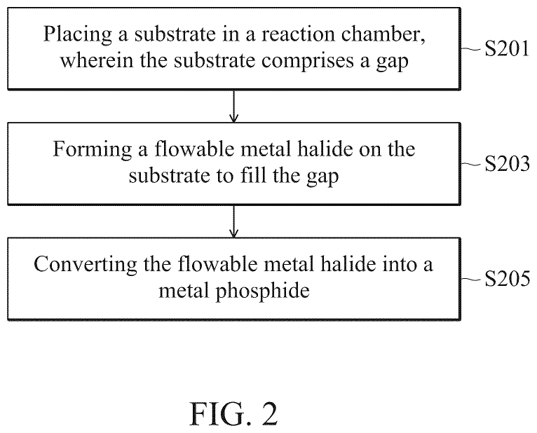

Another aspect of the present disclosure is providing a method of filling a gap. FIG. 2 is a flowchart of a method of filling a gap according to an embodiment of the present disclosure. As shown in FIG. 2, the method includes the following steps. Step S201 involves placing a substrate in the reaction chamber, wherein the substrate includes a gap. Step S203 involves forming a flowable metal halide on the substrate to fill the gap. Step S205 involves converting the flowable metal halide into a metal phosphide.

The step S201, step S203, and step S205 may be performed in sequence. That is, step S205 of converting the flowable metal halide into a metal phosphide may be performed after step S203 of forming the flowable metal halide on the substrate to fill the gap, but the disclosure is not limited thereto. In some embodiments, step S205 of converting the flowable metal halide into a metal phosphide may be performed before step S203 of forming the flowable metal halide on the substrate to fill the gap.

A deposition cycle including step S201, step S203, and step S205 may be performed one or more times until a sufficient amount of metal phosphide is deposited or the gap is filled. Furthermore, in each deposition cycle, each of the step S203 and step S205 may be performed one or more times. In some embodiments, at least one of step S203 and step S205 may be performed more than one time. In some embodiments, step S203 of forming a flowable metal halide on the substrate to fill the gap may be repeated more than once before step S205 of converting the flowable metal halide into a metal phosphide, but the disclosure is not limited thereto. In some embodiments, step S205 of converting the flowable metal halide into a metal phosphide may be performed more than once.

The substrate provided in step S201 may be the same as above, and therefore the details will not be repeated here.

In some embodiments, the substrate provided in step S201 may have a substrate temperature of less than 800° C., or of at least 50° C. to at most 500° C., or of at least 100° C. to at most 300° C., or of at least −25° C. to at most 400° C., or of at least 0° C. to at most 200° C., or of at least 25° C. to at most 150° C., or of at least 50° C. to at most 100° C.

In some embodiments, the reaction chamber may have a pressure of less than 760 Torr or of at least 0.2 Torr to at most 760 Torr, of at least 1 Torr to at most 100 Torr, or of at least 1 Torr to at most 10 Torr.

In some embodiments, the flowable metal halide formed in step S203 may be a metal halide that is liquid, or that can form a liquid, under the conditions in which it is formed. In some embodiments, the flowable metal halide may only be temporarily in a flowable state and would be formed into a solid material in the subsequent process. For example, in one embodiment, the “flowable metal halide” may be temporarily formed by the formation of liquid oligomers from gaseous monomers during a polymerization reaction and form a solid material in the subsequent step. The flowable metal halide formed in step S203 may flow into the gaps, the voids, or the seams of the substrate by at least one of capillary forces, surface tension, and gravity.

In some embodiments, the flowable metal halide may include CrF₅, BiF₅, GeF₂, GeF₄, SbF₃, SbF₅, AuF₃, AgF₃, TaF₅, VF₄, VF₅, TiF₄, Mo₆Cl₁₂, MoCl₄, AlCl₃, SnCl₂, ZnCl₂, NbCl₄, TaCl₅, ZrCl₄, HfCl₄, RhBr₃, FeBr₂, FeBr₃, MoBr₃, SnBr₃, InBr₃, Te₂Br, PtBr₄, NiBr₂, CuBr₂, VBr₃, AuBr, TaBr₅, ZrBr₄, VBr₃, MoI₃, AlI₃, CoI, ZnI₂, NbI₅, TaI₅, ZrI₄, HfI₄, WOBr₄, WOCl₄, NbOCl₃, V₂O₂F₄, VOCl₂, VOCl₃, VOF₃, ZrF₆(H₂O)₂, CoCl₂(H₂O)₂, or a combination thereof.

In step S203, the flowable metal halide may be form on the substrate provided in step S201 by any suitable process. In some embodiments, the flowable metal halide may be deposited on the substrate in a cyclical deposition process, wherein the cyclical deposition process may include cyclical CVD, ALD, or a hybrid cyclical CVD/ALD process.

In some embodiments, a layer of the flowable metal halide is conformally deposited on the substrate. In other words, the layer of the flowable metal halide may have a thickness which is constant over the surface of the substrate, including in gaps, recesses, and the like, e.g. within a margin of error of 50%, 20%, 10%, 5%, 2%, 1%, 0.5%, or 0.1%.

In some embodiments, step S203 may be performed at a substrate temperature of less than 800° C., or of at least 50° C. to at most 500° C., or of at least 100° C. to at most 300° C. In some embodiments, step S203 may be performed at a substrate temperature of at least −25° C. to at most 300° C., or of at least 0° C. to at most 250° C., or of at least 25° C. to at most 200° C., or of at least 50° C. to at most 150° C., or of at least 75° C. to at most 125° C. The step S203 may be performed at the same or a different substrate temperature than step S201.

In some embodiments, step S203 may be performed at a pressure of at most 10.0 Torr, or of at most 5.0 Torr, or of at most 3.0 Torr, or of at most 2.0 Torr, or of at most 1.0 Torr, or of at most 0.1 Torr, or of at most 10⁻² Torr, or of at most 10⁻³ Torr, or of at most 10⁻⁴ Torr, or of at most 10⁻⁵ Torr, or of at least 0.1 Torr to at most 10 Torr, or of at least 0.2 Torr to at most 5 Torr, or of at least 0.5 Torr to at most 2.0 Torr. The step S203 may be performed at the same or a different pressure than step S201.

In some embodiments, step S203 of forming the flowable metal halide may include introducing a vapor-phase metal precursor into the reaction chamber and introducing a vapor-phase halogenating agent into the reaction chamber, but the disclosure is not limited thereto. In such embodiments, the vapor-phase metal precursor may chemisorb to the substrate, leaving metal-ligand bonds on a surface of the substrate, and the metal-ligand bonds may be converted to a flowable metal halide by contact with the vapor-phase halogenating agent. The flowable metal halide may include flowable halo-oligomers/polymers that undergo chain growth as the metal precursor and the halogenating agent polymerizes.

In some embodiments, each of the vapor-phase metal precursor and the vapor-phase halogenating agent may be introduced at a substrate temperature of less than 800° C., or of at least 50° C. to at most 500° C., or of at least 100° C. to at most 300° C. In some embodiments, step S203 may be performed at a substrate temperature of at least −25° C. to at most 300° C., or of at least 0° C. to at most 250° C., or of at least 25° C. to at most 200° C., or of at least 50° C. to at most 150° C., or of at least 75° C. to at most 125° C. The vapor-phase metal precursor and the vapor-phase halogenating agent may be introduced at the same or different substrate temperatures.

In some embodiments, each of the vapor-phase metal precursor and the vapor-phase halogenating agent may be introduced at a pressure of at most 10.0 Torr, or of at most 5.0 Torr, or of at most 3.0 Torr, or of at most 2.0 Torr, or of at most 1.0 Torr, or of at most 0.1 Torr, or of at most 10⁻² Torr, or of at most 10⁻³ Torr, or of at most 10⁻⁴ Torr, or of at most 10⁻⁵ Torr, or of at least 0.1 Torr to at most 10 Torr, or of at least 0.2 Torr to at most 5 Torr, or of at least 0.5 Torr to at most 2.0 Torr. The vapor-phase metal precursor and the vapor-phase halogenating agent may be introduced at the same or different pressures.

In some embodiments, each of the vapor-phase metal precursor and the vapor-phase halogenating agent may be introduced in a pulse form for from at least 0.1 s (second) to at most 1000 s, or from at least 0.2 s to at most 500 s, or from at least 0.5 s to at most 200 s, or from at least 1.0 s to at most 100 s, or from at least 2 s to at most 50 s, or from at least 5 s to at most 20 s. The vapor-phase metal precursor may be introduced in the same or a different form as the vapor-phase halogenating agent.

The vapor-phase metal precursor may include a compound comprising a metal and a ligand selected from a cyclopentadienyl ligand, an alkoxide ligand, an alkylamido ligand, an amidinate ligand, an alkyl ligand, a beta-diketonate ligand, or a combination thereof. The metal may be selected from a group consisting of Al, In, Sn, Bi, Ge, Sb, Te, Rh, Fe, Cr, Mo, Au, Pt, Ag, Ni, Cu, Co, Zn, Nb, Ta, V, Ti, Zr, Hf, W, or a combination thereof.

The halogenating agent may be selected from a diatomic halogen molecule, a hydrogen halide, an alkyl halide, an alkyl dihalide, an aryl halide, an acyl halide, an aryl dihalide, a halosilane, a metal halide, a boron halide, phosphorus halide, sulfur halide, N-chlorosuccinimide, N-bromosuccinimide, N-iodosuccinimide, 1,1-difluoroalkylamine, or a combination thereof.

In step S205, the flowable metal halide formed in step S203 may be converted into a metal phosphide film. In some embodiments, step S205 can be performed after all of the flowable metal halide has been deposited. Alternatively, step S205 can be done cyclically. The flowable metal halide formed in step S203 may be converted into a metal phosphide film as it undergoes a chemical reaction.

In some embodiments, in step S205, the flowable metal halide formed in step S203 may be converted into a metal phosphide film as it undergoes a chemical reaction with the phosphorus-containing precursor. The step S205 may include introducing a vapor-phase phosphorus-containing precursor into the reaction chamber.

In some embodiments, step S205 may be performed at a substrate temperature of less than 800° C., or of at least −25° C. to at most 800° C., or of at least 0° C. to at most 700° C., or of at least 25° C. to at most 600° C., or of at least 50° C. to at most 400° C., or of at least 75° C. to at most 200° C., or of at least 100° C. to at most 150° C. The step S205 may be performed at the same substrate temperature as step S203 or at a different temperature.

In some embodiments, step S205 may be performed at a pressure of at most 10.0 Torr, or of at most 5.0 Torr, or of at most 3.0 Torr, or of at most 2.0 Torr, or of at most 1.0 Torr, or of at most 0.1 Torr, or of at most 10⁻² Torr, or of at most 10⁻³ Torr, or of at most 10⁻⁴ Torr, or of at most 10⁻⁵ Torr, or of at least 0.1 Torr to at most 10 Torr, or of at least 0.2 Torr to at most 5 Torr, or of at least 0.5 Torr to at most 2.0 Torr. The step S205 may be performed at the same pressure as step S203 or at different pressure.

In some embodiments, in step S205, the vapor-phase phosphorus-containing precursor may be introduced in a pulse form for from at least 0.1 s (second) to at most 1000 s, or from at least 0.2 s to at most 500 s, or from at least 0.5 s to at most 200 s, or from at least 1.0 s to at most 100 s, or from at least 2 s to at most 50 s, or from at least 5 s to at most 20 s, or from at least 1.0 s to at most 3 s. The vapor-phase phosphorus-containing precursor may be introduced in the same or a different form as the vapor-phase metal precursor or the vapor-phase halogenating agent.

The vapor-phase phosphorus-containing precursor used in step S205 may include a silylphosphine or alkylsilylphosphine. In some embodiments, the silylphosphine or alkylsilylphosphine may be represented by the formula:

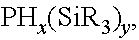

wherein x is an integer from 0 to 2, y=3−x, and each R is independently hydrogen, a C₁-C₁₀ alkyl group, or a C₆-C₁₀ aryl group. In some embodiments, each R is independently a C₁-C₈ alkyl group, a C₁-C₆ alkyl group, or a C₁-C₄ alkyl group. In some embodiments, all R are the same. In some embodiments, at least one R is H. In some embodiments, none of the R is H. In some embodiments, x=0, y=3, and R are all methyl groups or all ethyl groups. The definition of the term “C₁-C₁₀ alkyl group” used here may be the same as above. It is therefore not repeated here.

In some embodiments, the method of the present disclosure may further include purging steps between each step to remove any excess precursor and/or reaction by-products. In some embodiments, each purging step may include introducing an inert or substantially inert gas into the reaction chamber between any two steps.

The method of the present disclosure may provide a substrate without gaps, voids, or seams. The method of the present disclosure can be advantageously used in the field of integrated circuit manufacture.

In some embodiments, the metal phosphide film deposited according to methods disclosed herein is a threshold voltage shifting layer. The term “threshold voltage” as used herein refers to a minimum gate voltage required to create a conductive path between the source and drain terminals of a field effect transistor. The term “threshold voltage shifting layer” as used herein refers to a layer which is useful for controlling the threshold voltage of a metal oxide field effect transistor. Thus, it refers to a layer which can be used in the gate stack of a field effect transistor, and which can change the threshold voltage of that field effect transistor. It may be equivalent to similar terms such as “threshold voltage tuning layer”, “dipole layer”, or “threshold voltage controlling layer”. In some embodiments, a molybdenum phosphide layer deposited according to the current disclosure is a threshold voltage tuning layer.

In some embodiments, the metal phosphide film deposited according to methods disclosed herein are used as a dipole layer in a metal gate.

In some embodiments, the metal phosphide film deposited according to methods disclosed herein are used as a conductive material in interconnects.

In some embodiments, the metal phosphide film deposited according to methods disclosed herein are used to form a phosphorus-containing MAX phase material.

Yet a further aspect of the present disclosure provides a system for forming a metal phosphide film. The system includes a reaction chamber, a first precursor source comprising a metal precursor, a second precursor source comprising a halogenating agent, a third precursor source comprising a phosphorus-containing precursor, and a controller. The controller is configured to control gas flow into the reaction chamber to form a metal phosphide on a substrate by means of a method as described herein. Each of the metal precursor, the halogenating agent and the phosphorus-containing precursor may be gaseous, liquid or solid in the precursor source. In some embodiments, the first precursor source contains a liquid metal precursor. In some embodiments, the first precursor source contains a gaseous metal precursor. In some embodiments, the first precursor source contains a solid metal precursor, In some embodiments, the second precursor source contains a liquid halogenating agent. In some embodiments, the second precursor source contains a gaseous halogenating agent. In some embodiments, the second precursor source contains a solid halogenating agent. In some embodiments, the third precursor source contains a liquid phosphorus-containing precursor. In some embodiments, the third precursor source contains a gaseous phosphorus-containing precursor. In some embodiments, the third precursor source contains a solid phosphorus-containing precursor. The metal precursor, the halogenating agent and the phosphorus-containing precursor are vaporized for delivery into the reaction chamber in vapor phase.

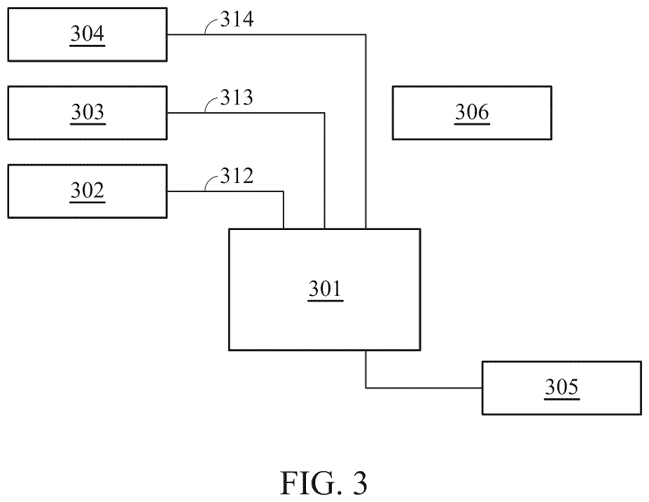

FIG. 3 is a schematic view of a system 300 according to an embodiment of the present disclosure. The system 300 can be used to perform a method as described herein. As shown in FIG. 3, the system 300 includes one or more reaction chambers 301, a first precursor source 302, a second precursor source 303, a third precursor source 304, an exhaust 305, and a controller 306.

The reaction chamber 301 can include any suitable reaction chamber, such as an ALD or CVD reaction chamber. In some embodiments, the reaction chamber may include a showerhead injector and a substrate support (not shown).

The first precursor source 302 may include a vessel and the vapor-phase metal precursor mentioned above alone or mixed with one or more carrier (e.g., noble) gases. The second precursor source 303 may include a vessel and the vapor-phase halogenating agent mentioned above alone or mixed with one or more carrier gases. The third precursor source 304 may include a vessel and the vapor-phase phosphorus-containing precursor mentioned above alone or mixed with one or more carrier gases. The precursor source 302-304 may be coupled to reaction chamber 301 via lines 312-314, which can each include flow controllers, valves, heaters, and the like. Although illustrated with the precursor source 302-304, the system 301 can include any suitable number of gas sources. In some embodiments, the system 300 may further include purge gas source to introduce one or more inert gases to the reaction chamber 301. The exhaust 305 may be coupled to reaction chamber 301 to remove any excess precursor and/or reaction by-products. The exhaust 305 may include one or more vacuum pumps.

The controller 306 may include an electric circuit and a software to selectively operate components, e.g. the valves, manifolds, heaters, pumps, or other elements included in the system 300. The electric circuit and components operate to introduce the precursors and/or purge gases from the respective sources. The controller 306 can control timing of gas pulse sequences, temperature of the substrate and/or reaction chamber, pressure within the reaction chamber, and various other operations to provide proper operation of the system 300. The controller 306 can include control software to electrically or pneumatically control valves to control flow of precursors and/or purge gases into and out of the reaction chamber 301. The controller 306 can include modules such as a software or hardware component, e.g., a field programmable gate array (FPGA) or an application specific integrated circuit (ASIC), which performs certain tasks. A module can advantageously be configured to reside on the addressable storage medium of the control, and be configured to execute one or more processes.

Other configurations of the system 300 are possible, including different numbers and kinds of precursor sources and purge gas sources. Further, it will be appreciated that there are many arrangements of valves, conduits, precursor sources, and purge gas sources that may be used to accomplish the goal of selectively feeding gases into the reaction chamber 301. Further, as a schematic representation of a system, many components have been omitted for simplicity of illustration, and such components may include, for example, various valves, manifolds, purifiers, heaters, containers, vents, and/or bypasses.

The system can be used to perform the method of the present disclosure which may provide a substrate without gaps, voids, or seams. The system can be advantageously used in the field of integrated circuit manufacture.

Although embodiments of the present disclosure and the advantages thereof have been disclosed as described above, it should be understood that changes, substitutions and modifications may be made without departing from the spirit and scope of the disclosure. In addition, the protection scope of the present disclosure is not limited to the processes, machines, fabrications, compositions, devices, methods and steps in the specific embodiments described in the specification. According to the embodiments of the present disclosure, a person of ordinary skill in the art may understand that current or future processes, machines, fabrications, compositions, devices, methods and steps capable of performing substantially the same functions or achieving substantially the same results may be used in the embodiments of the present disclosure. Therefore, the protection scope of the present disclosure includes the above-mentioned processes, machines, fabrications, compositions, devices, methods and steps. In addition, features of different embodiments may be used together arbitrary as long as they do not violate the spirit of the disclosure or conflict with each other. Each claim constitutes an individual embodiment, and the protection scope of the present disclosure includes the combination of the claims and embodiments.

What is claimed is:

1. A method of forming a metal phosphide film on a substrate using a cyclical deposition process, wherein the method comprises:
contacting the substrate with a vapor-phase metal precursor;
contacting the substrate with a vapor-phase halogenating agent; and
contacting the substrate with a vapor-phase phosphorus-containing precursor.

2. The method as claimed in claim 1, wherein contacting the substrate with the vapor-phase halogenating agent is performed after contacting the substrate with the vapor-phase metal precursor, and contacting the substrate with the vapor-phase phosphorus-containing precursor is performed after contacting the substrate with the vapor-phase halogenating agent.

3. The method as claimed in claim 1, wherein contacting the substrate with the vapor-phase metal precursor and contacting the substrate with the vapor-phase halogenating agent are repeated at least once before contacting the substrate with the vapor-phase phosphorus-containing precursor.

4. The method as claimed in claim 1, wherein the phosphorus-containing precursor comprises a silylphosphine.

5. The method as claimed in claim 4, wherein the silylphosphine or alkylsilylphosphine is represented by the formula: PHₓ(SiR₃)_{y},
wherein x is an integer from 0 to 2, y=3−x, and each R is independently hydrogen or a C₁-C₁₀ alkyl group.

6. The method as claimed in claim 1, wherein the metal precursor comprises a compound comprising a metal and a ligand selected from a cyclopentadienyl ligand, an alkoxide ligand, an alkylamido ligand, an amidinate ligand, an alkyl ligand, a beta-diketonate ligand, or a combination thereof.

7. The method as claimed in claim 6, wherein the metal is selected from group 3 to group 15 metals.

8. The method as claimed in claim 7, wherein the metal forms a flowable halide compound.

9. The method as claimed in claim 1, wherein the halogenating agent is selected from a diatomic halogen molecule, a hydrogen halide, an alkyl halide, an aryl halide, an acyl halide, a halosilane, a metal halide, a boron halide, phosphorus halide, sulfur halide, N-chlorosuccinimide, N-bromosuccinimide, N-iodosuccinimide, 1,1-difluoroalkylamine, or a combination thereof.

10. A method of filling a gap, the method comprising:
placing a substrate in a reaction chamber, wherein the substrate comprises a gap;
forming a flowable metal halide on the substrate to fill the gap; and
converting the flowable metal halide into a metal phosphide.

11. The method as claimed in claim 10, wherein the step of forming the flowable metal halide comprises:
introducing a vapor-phase metal precursor into the reaction chamber; and
introducing a vapor-phase halogenating agent into the reaction chamber.

12. The method as claimed in claim 11, wherein the metal precursor comprises a compound comprising a metal and a ligand selected from a cyclopentadienyl ligand, an alkoxide ligand, an alkylamido ligand, an amidinate ligand, an alkyl ligand, a beta-diketonate ligand, or a combination thereof.

13. The method as claimed in claim 12, wherein the metal is selected from a group consisting of Al, In, Sn, Bi, Ge, Sb, Te, Rh, Fe, Cr, Mo, Au, Pt, Ag, Ni, Cu, Co, Zn, Nb, Ta, V, Ti, Zr, Hf, W, or a combination thereof.

14. The method as claimed in claim 11, wherein the halogenating agent is selected from a diatomic halogen molecule, a hydrogen halide, an alkyl halide, an aryl halide, an acyl halide, a halosilane, a metal halide, a boron halide, phosphorus halide, sulfur halide, N-chlorosuccinimide, N-bromosuccinimide, N-iodosuccinimide, 1,1-difluoroalkylamine, or a combination thereof.

15. The method as claimed in claim 10, wherein the step of converting the flowable metal halide into a metal phosphide comprises introducing a vapor-phase phosphorus-containing precursor into the reaction chamber.

16. The method as claimed in claim 15, wherein the phosphorus-containing precursor comprises a silylphosphine.

17. A system for forming a metal phosphide film, comprising:
a reaction chamber;
a first precursor source comprising a metal precursor;
a second precursor source comprising a halogenating agent;
a third precursor source comprising a phosphorus-containing precursor; and
a controller, wherein the controller is configured to control gas flow into the reaction chamber to form a metal phosphide on a substrate by means of a method according to claim 1.
